(19) United States
(12) Patent Application Publication
(10) Pub. No.: US 2008/0142475 A1
(43) Pub. Date: Jun. 19, 2008

(54) METHOD OF CREATING SOLID OBJECT FROM A MATERIAL AND APPARATUS THEREOF

(75) Inventors: Peter V. Loeppert, Hoffmann Estates, IL (US); Anthony Minervini, Palos Hills, IL (US); Jay Cech, St. Charles, IL (US); Sung B. Lee, Chicago, IL (US)

Correspondence Address: FITCH EVEN TABIN AND FLANNERY, 120 SOUTH LA SALLE STREET, SUITE 1600, CHICAGO, IL, 60603-3406, US

(73) Assignee: KNOWLES ELECTRONICS, LLC, Itasca, IL (US)

(21) Appl. No.: 11/611,633

(22) Filed: Dec. 15, 2006

(51) Int. Cl. C30B 33/08

(52) U.S. Cl. 216/23; 216/87

(57) ABSTRACT

A directed energy source is applied to a portion of a material, creating at least one altered region and leaving at least one unaltered region. The material is exposed to an etchant which removes the at least one altered region leaving substantially all of the unaltered region.

### FIELD OF INVENTION

The patent relates to the formation of arbitrary three-dimensional (3-D) structures from a solid material.

### BACKGROUND OF INVENTION

Prior approaches for forming 3-D structures involve masking at least one surface of a substrate material, patterning the mask, and exposing the substrate to an etchant. The etching may proceed via a wet or dry process and may further be characterized as isotropic or anisotropic. Generally, the etched region is a projection of the masked pattern into the substrate perpendicular to the masked surface. There is limited control of the sidewall slope through the choice of etching process and there is no way to laterally etch regions arbitrarily. The only approach to form such structures involves repetitive deposition and etches cycles which are both complicated and expensive.

When etching a material such as single crystalline silicon in an anisotropic etchant such as potassium hydroxide (KOH), certain crystal planes will typically etch much faster than others. For instance, in silicon the (100) planes etch much faster than the (111) planes. Furthermore, polycrystalline regions etch faster than (100) planes and amorphous regions etch a hundred times faster than the (100) planes in silicon.

Rapidly heating a region of a crystalline silicon followed by a sudden quench to room temperature destroys the crystalline nature of the region causing the crystalline silicon to become amorphous or at least fine grained poly crystalline material. The rapid heating can be accomplished by focusing a pulsed directed energy source into a material such that at the focal point, the power density exceeds a critical value. In doing so, only the region in the immediate vicinity of the focal point will have its crystalline structure altered.

In one previous approach, a laser was used as the directed energy source to create linear regions of altered material across a wafer and through the thickness of the wafer whereby the wafer can be easily broken into many individual die. This approach includes a critical power density for silicon of 10⁸ W/cm² with a pulse width of less than 1 μS and may be described as multi-photon absorption at the focal point. The wavelength used was typically below the band gap absorption edge thus being only slightly absorbed if at all. The regions below the critical power density therefore are not altered. Adding a masking material in addition to the laser exposure adds another degree of freedom to the process by either blocking the energy or aiding in the coupling of the energy to the material by the selection of appropriate optical properties, i.e. reflective vs. antireflective.

### BRIEF DESCRIPTION OF THE DRAWINGS

For a more complete understanding of the disclosure, reference should be made to the following detailed description and accompanying drawings wherein:

FIG. 1 is a perspective view of a directed energy source device applying a directed energy source to a material in accordance with an exemplary embodiment of the present invention;

FIG. 2 is a perspective view of an altered region caused by the device of FIG. 1 prior to etching as formed according to the present invention;

FIG. 3 is a cross sectional view of the solid object of FIG. 2 according to the present invention;

FIG. 4 is a cross sectional view of another embodiment of a solid object according to the present invention;

FIG. 5 is a cross sectional view of a Microelectromechanical system (MEMS) device according to the present invention; and

FIG. 6 is a cross sectional view of the MEMS device of FIG. 5 according to the present invention.

Skilled artisans will appreciate that elements in the figures are illustrated for simplicity and clarity. It will further be appreciated that certain actions and/or steps may be described or depicted in a particular order of occurrence while those skilled in the art will understand that such specificity with respect to sequence is not actually required. It will also be understood that the terms and expressions used herein have the ordinary meaning as is accorded to such terms and expressions with respect to their corresponding respective areas of inquiry and study except where specific meanings have otherwise been set forth herein.

### DETAILED DESCRIPTION

While the present disclosure is susceptible to various modifications and alternative forms, certain embodiments are shown by way of example in the drawings and these embodiments will be described in detail herein. It will be understood, however, that this disclosure is not intended to limit the invention to the particular forms described, but to the contrary, the invention is intended to cover all modifications, alternatives, and equivalents falling within the spirit and scope of the invention defined by the appended claims. Like reference numerals are used for like and corresponding elements of the drawings.

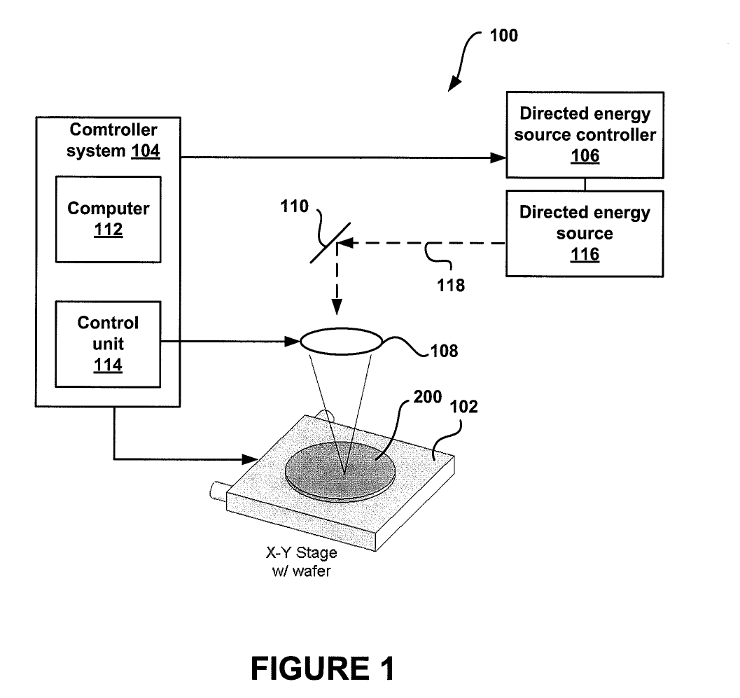

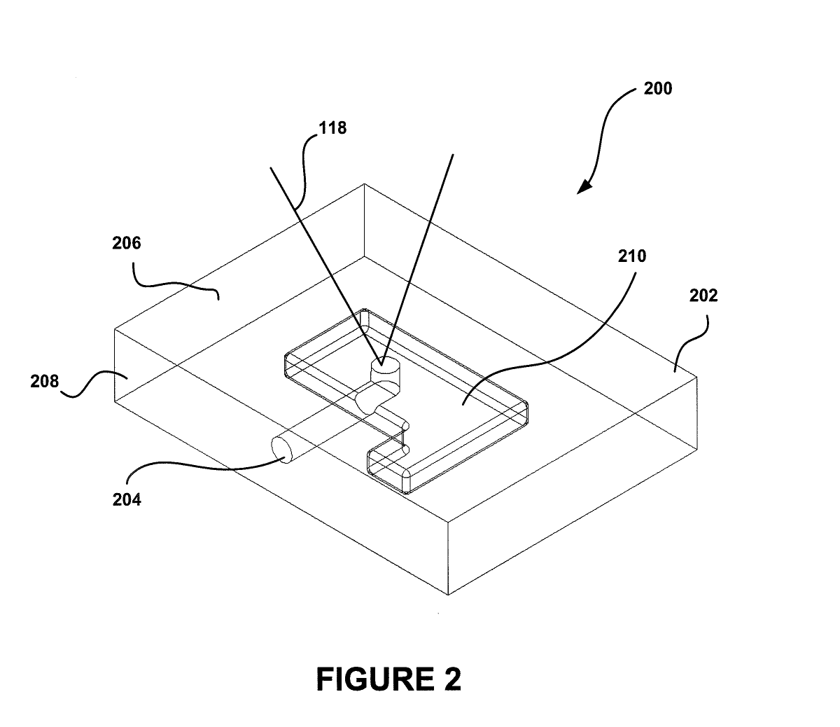

FIG. 1 illustrates a device 100 for applying a directed energy source to a material 200. The device 100 comprises a fixture 102, a controller system 104, a directed energy source 116 with a controller 106, a lens 108, and a mirror 110. The material 200 is held in place on the fixture 102. The material 200 may exist in any solid state form, for example, single crystalline, polycrystalline, amorphous, polymeric, or a combination thereof to be processed with the directed energy source 116, so as to form at least one altered region 210 (as shown in FIG. 2) within the material 200 and will discussed in detail therein. The material 200 may be silicon (Si), germanium (Ge), gallium arsenide (GaAs), and/or other suitable semiconductor material. In one example, the material 200 is a Si wafer. The material 200 may take the form of various scales and sizes based on the intended applications and operating conditions.

It is contemplated that the present approaches are not limited to crystalline materials. Rather, solid materials such as polymers can undergo structural/chemical changes when a critical power density is reached thereby forming altered regions which can be preferentially etched over unaltered regions. Depending on the material and etchant properties, the opposite process is also contemplated in which the unaltered region is preferentially etched over altered regions.

An optional masking material (not shown) being resistant to attack by an etchant (not shown) is applied to at least a portion the material for protecting an underling region of the material 200 and will be discussed in greater detail herein. The fixture 102 for mounting the material 200 can be a motion stage which is controlled and moved by the controller system 104 in an x-direction, a y-direction, an a z-direction, and any combination thereof.

The controller system 104 comprises a computer 112 and a control unit 114. The computer 112 is any type of device capable of processing, transmitting, and receiving data from a user. The computer 112 may provide a Graphical User Interface (GUI) to a user or users. The computer 112 may provide other functions, as well. The computer 112 also controls the operations of the control unit 114. The control unit 114 is a motion stage controller for controlling the movement of the fixture 102. The directed energy source controller 106 for controlling at least one energy source 116, producing at least one energy beam 118 which is reflected by the mirror 110 and is focused into the material 200 by lens 108. The focal point of beam 118 within material 200 may be controlled in the direction normal to the surface (Z axis) by either adjusting the lens 108 or by Z motion of the fixture 102. In one embodiment, the directed energy source 116 is a laser and its wavelength is selected based the optical properties of material 200. In the example of silicon material, the energy source 116 has a wavelength to be approximately 1000 nm and longer so that at low intensities it is not absorbed. Alternatively, the energy source 116 has a wavelength of approximately 1500 nm. In one embodiment, the wavelengths for use with silicon are approximately 1064 nm and approximately 1300 nm. Other examples of energy source are possible. A plurality of energy beams (not shown) may be emitted from the directed energy source 116 to different locations within the material 200, so as to form at least one altered region 210 (See FIG. 2) and leaving at least one unaltered region 202 (See FIG. 2). Alternatively a plurality of beams can be focused at the same location to achieve the critical power density level.

Referring now to FIG. 2, a perspective view of a material 200 is illustrated. At least one directed energy source beam 118 generated by the directed energy source 106 (See FIG. 1) is applied to a portion of the material 200 so as to form at least one region in which a certain structure has undergone a change into another crystal structure, defining an altered region 210, leaving at least one unaltered region 202. As mentioned with respect to FIG. 1, the material 200 may exist in any solid state form, for example, single crystalline, polycrystalline, amorphous, polymeric, or a combination thereof. For example, the altered region 210 is created by changing from single crystal structure to polycrystalline structure, single crystal structure to amorphous structure, or single crystal structure to a combined polycrystalline and amorphous structure. The altered region 210 may be formed from an entrance face 208 through channel 204 and extends to an inside 206 of the material 200 and vice versa, thus providing an access point for an etchant.

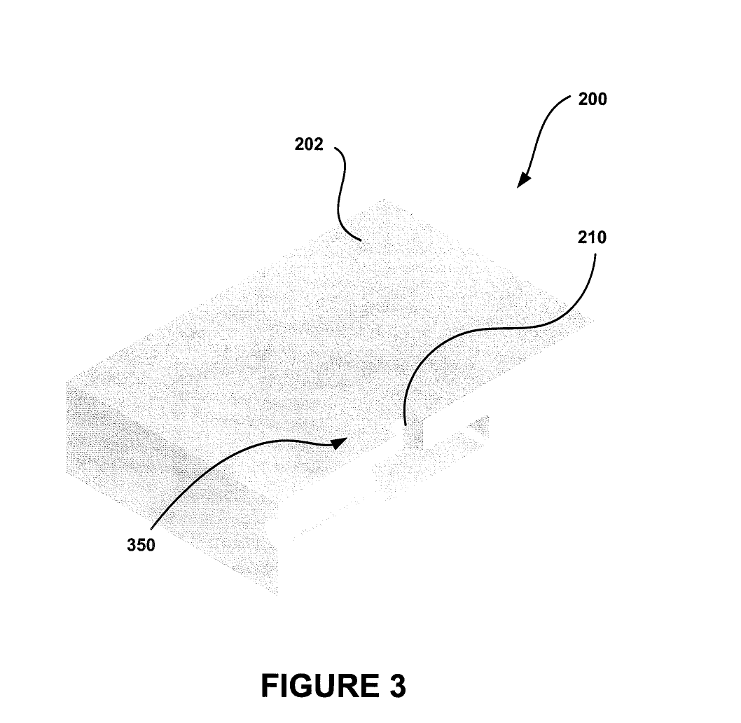

FIG. 3 illustrates a structure 350 is formed from a material 200 using the approaches described herein. The material 200 is introduced to an etchant so that the altered region 210 is removed, defining the structure 350, and leaving substantially all of the unaltered region 202. The structure 350 can contain features such as holes, channels, recesses, pits, vias, grooves, trenches, cantilevers, voids, undercuts, or a combination thereof. Other examples are possible. The etchant is a solution selected from a group consisting of a wet etchant, a dry etchant, and/or other suitable solution for removal of the altered region. In one example where the material is silicon, the etchant can be Potassium Hydroxide (KOH), Tetramethylamonium Hydroxide (TMAH), or Ethylene Diamine Pyrocatechol (EDP). Other examples of etchant solutions are possible.

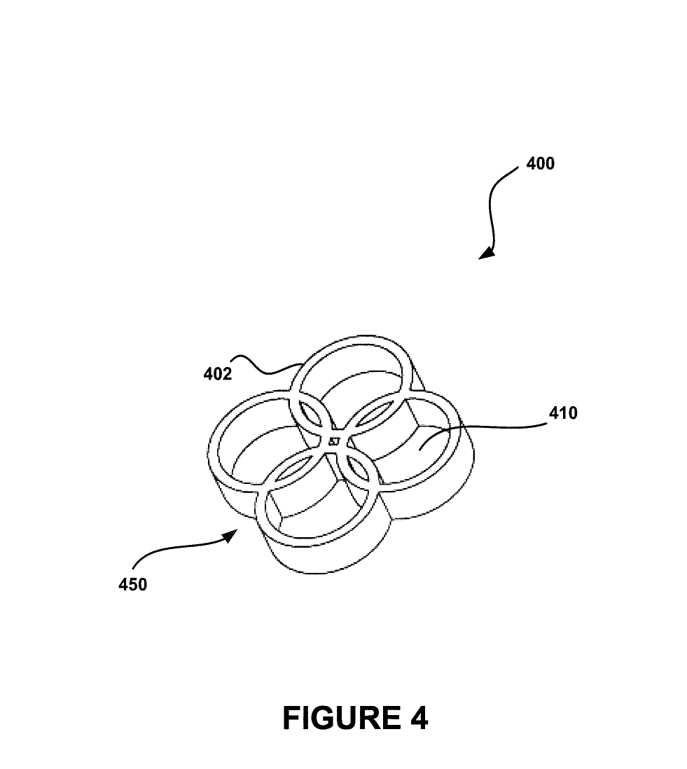

Another example of applying the present approaches to form a structure in a material is illustrated in FIG. 4. The embodiment 400 is similar to the embodiment illustrated in FIGS. 2-3, and like elements are referred to using like reference numerals wherein, for example, 202 and 210 correspond to 402 and 410, respectively. The material 400 is introduced into an etchant so that the altered region 410 is removed and leaving substantially all of the unaltered region 402, defining a structure 450. The shape of the structure 450 may be varied based on the intended application and operating conditions and its orientation within material 400 is not dependent on the direction from which the directed energy source beam 118 arrives.

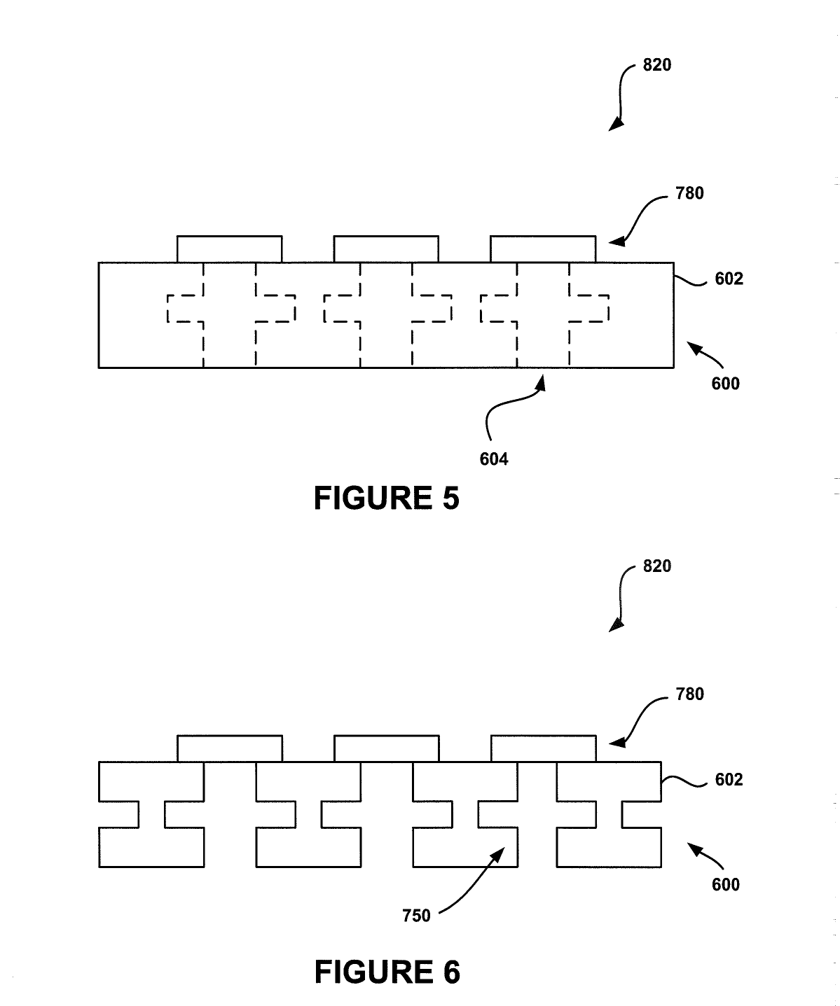

FIGS. 5-6 illustrate a Microelectromechanical System (MEMS) device 820 formed by using the approaches described herein. The device 820 may be employed in virtually any industries. One or more semiconductor devices 780 are formed on a material 600 by any suitable methods of attachment. The one or more semiconductor devices 780 may be transducers, sensors, actuators, accelerometers, or a combination thereof. In one example, the semiconductor device 780 is a transducer. The transducer may be a microphone, a receiver, or combination thereof. Other examples are possible. The material 600 comprises a plurality of features 750 in which the features 750 are obtained by irradiating a portion of the material 600 with a directed energy source to create a portion of an altered region 604 and then removing the altered region 604 using an etchant. The features 750 can be holes, channels, recesses, pits, vias, grooves, trenches, cantilevers, voids, undercuts, or any combination thereof. Other examples are possible.

All references, including publications, patent applications, and patents, cited herein are hereby incorporated by reference to the same extend as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. It should be understood that the illustrated embodiments are exemplary only, and should not be taken as limiting the scope of the invention.

What is claimed is:

1. A method of creating a solid object from a material comprising:
applying a directed energy source to a portion of a material, creating at least one altered region and leaving at least one unaltered region; and
exposing the material to an etchant which removes the at least one altered region leaving substantially all of the unaltered region.

2. The method of claim 1, wherein the material comprises a single crystal solid.

3. The method of claim 2, wherein the material comprises silicon.

4. The method of claim 1, wherein the altered region comprises at least one structure selected from a group consisting of non-crystalline and poly crystalline.

5. The method of claim 1, wherein the directed energy source comprises a laser.

6. The method of claim 1, wherein the directed energy source has a wavelength between 1000 nm and 1500 nm.

7. The method of claim 1, wherein removal of the altered region defines a feature selected from the group consisting of a hole, a channel, a recess, a pit, a via, a groove, a trench, a cantilever, a void, an undercut, and a combination thereof.

8. The method of claim 7, wherein at least a portion of the altered region is a shared surface with the material.

9. The method of claim 1, further comprising:
providing a masking material, the masking material being applied to the material to protect an underlying region of the material from the etchant.

10. The method of claim 1, wherein the etchant is selected from a group consisting of a wet etchant, a dry etchant, and a combination thereof.

11. The method of claim 1, wherein the etchant is a solution selected from a group consisting of Potassium Hydroxide (KOH), Tetramethylamonium Hydroxide (TMAH), or Ethylene Diamine Pyrocatechol (EDP).

12. The method of claim 1, wherein the solid object comprises at least a portion of a MEMS device.

13. A method of creating a solid object from a material comprising:
irradiating a portion of material with a directed energy source and creating at least one altered region; and
introducing the material into an etchant, the etchant removing the altered region.

14. The method of claim 13, wherein:
the material is selected from a group consisting of a single crystal solid and a near single crystal solid;
the altered region comprises at least one structure selected from a group consisting of non-crystalline and polycrystalline;
the directed energy source is a laser with a wavelength that is substantially absorbed by the material at high intensity; and
the etchant comprises an anisotropic etching solution thereby removing the altered region.

15. The method of claim 13, providing a masking material to the portion of the material, the masking material being resistant to attack by the etchant and protecting an underlying region of the material from the etchant.

16. A method of creating a solid object from a crystalline material comprising:
irradiating a portion of a crystalline material with a laser creating at least one noncrystalline region while leaving at least one crystalline region; and
exposing the crystalline material to an etchant thereby removing the noncrystalline region and leaving substantially all of the crystalline region.
